(19) United States
(12) Patent Application Publication
(10) Pub. No.: US 2015/0371901 A1
(43) Pub. Date: Dec. 24, 2015

(54) METHOD OF MANUFACTURING SEMICONDUCTOR DEVICE

(71) Applicant: Sumitomo Electric Industries, Ltd., Osaka-shi (JP)

(72) Inventor: Mitsuhiko SAKAI, Osaka-shi (JP)

(21) Appl. No.: 14/699,520

(22) Filed: Apr. 29, 2015

(30) Foreign Application Priority Data
Jun. 19, 2014 (JP) 2014-126114

(51) Int. Cl. H01L 21/78

(52) U.S. Cl. CPC H01L 21/78

(57) ABSTRACT

A method of manufacturing a semiconductor device includes a step of preparing a semiconductor substrate including a semiconductor layer and an epitaxial layer formed on the semiconductor layer, a first division step of obtaining first individual pieces by dividing the semiconductor substrate so as to pass through a central region including a central point of the semiconductor substrate and having a diameter of 10 mm, and a second division step of obtaining second individual pieces by subdividing the first individual piece.

### BACKGROUND OF THE INVENTION

1. Field of the Invention

The present invention relates a method of manufacturing a semiconductor device.

2. Description of the Background Art

A wide band gap semiconductor represented by a silicon carbide (SiC) semiconductor has recently attracted attention as a material for forming a semiconductor device. By using a wide band gap semiconductor as a material for forming a device, a semiconductor device which is higher in breakdown voltage and lower in power consumption and is able to operate faster than a conventional silicon (Si) semiconductor device can be expected.

In general, owing to a wide band gap, a wide band gap semiconductor is high in bonding force between atoms and extremely high in hardness. Therefore, cracking is likely during division of a wafer (a substrate) with the use of a dicing saw, which is a cause of lowering in yield.

In order to address such a problem, various methods for division of a substrate have conventionally been proposed (see, for example, Japanese Patent Laying-Open No. 2011-146748, Japanese Patent Laying-Open No. 8-236867, and Japanese Patent Laying-Open No. 10-242570).

### SUMMARY OF THE INVENTION

Japanese Patent Laying-Open No. 2011-146748 has proposed a method of dividing a substrate by irradiating the substrate with electron beams to produce cracks. This method, however, is not suitable for division of a substrate having a large area (in particular, a substrate not smaller than 6 inches), because a speed of machining is lower than in general division with a dicing saw. Therefore, this method cannot adapt to increase in area of wide band gap semiconductor substrates which is expected in the future.

Japanese Patent Laying-Open No 8-236867 has proposed a method, in which a trench is formed in a sapphire substrate, thereafter a nitride-based semiconductor layer is selectively grown, and thereafter the substrate is divided along the trench. This method, however, inevitably suffers from increase in number of steps in correspondence with formation of the trench.

Japanese Patent Laying-Open No. 10-242570 has proposed a method for a semiconductor stack substrate having an underlying substrate composed of sapphire and a gallium nitride (GaN) based semiconductor layer stacked thereon, in which a cutting line is provided along a direction of cleavage of a crystal and the substrate is divided with this cutting line being defined as a starting point. With this method, however, a chip shape is restricted by a cleavage plane of the crystal. Therefore, for example, in a case that a semiconductor layer is an SiC (hexagonal) layer, a quadrangular chip cannot be cut from the substrate.

In view of the circumstances above, it is an object to improve yield in a method of manufacturing a semiconductor device including a step of dividing a semiconductor substrate into chips (individual pieces).

A method of manufacturing a semiconductor device according to one embodiment of the present invention includes a step of preparing a semiconductor substrate including a semiconductor layer and an epitaxial layer formed on the semiconductor layer, a first division step of obtaining first individual pieces by dividing the semiconductor substrate so as to pass through a central region including a central point of the semiconductor substrate and having a diameter of 10 mm, and a second division step of obtaining second individual pieces by subdividing the first individual piece.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view showing one example of a construction of a semiconductor substrate according to one embodiment of the present invention.

FIG. 2 is a schematic partial cross-sectional view along the line II-II FIG. 1.

FIG. 3 is a schematic diagram illustrating a first division step according to one embodiment of the present invention.

FIG. 4 is a schematic diagram illustrating a second division step according, to one embodiment of the present invention.

FIG. 5 is a flowchart showing overview of a method of manufacturing a semiconductor device according to one embodiment of the present invention.

### DESCRIPTION OF THE PREFERRED EMBODIMENTS

### Description of Embodiment of the Present Invention

Embodiments of the present invention will initially be listed and explained.

[1] A method of manufacturing a semiconductor device according to one embodiment of the present invention includes a step of preparing a semiconductor substrate including a semiconductor layer and an epitaxial layer formed on the semiconductor layer, a first division step of obtaining first individual pieces by dividing the semiconductor substrate so as to pass through a central region including a central point of the semiconductor substrate and having a diameter of 10 mm, and a second division step of obtaining second individual pieces by subdividing the first individual piece.

Susceptibility to cracking during division of a semiconductor substrate high in hardness may be attributed to residual strains or thermal strains in the substrate. Namely, it is suspected that residual strains or thermal strains are accumulated in a semiconductor substrate as the substrate goes through an epitaxial growth step and an ion implantation step, and when division is started from a portion other than a central region of the substrate, a machining stress applied to two divided regions becomes uneven and strains included in one region results in stress concentration, which leads to cracking.

In contrast, according to the manufacturing method above, division is carried out initially along the line passing through the central region of the semiconductor substrate. Thus, a machining stress applied to two divided regions becomes even and the semiconductor substrate can be divided with strains being released. In addition, since strains have already been eliminated from first individual pieces obtained in the initial division, the first individual piece can readily be sub divided into second individual pieces (chips).

Furthermore, according to the manufacturing method above, a dicing saw high in machining speed can be employed. Therefore, improvement in yield can be achieved substantially without increase in number of steps. Additionally, since a chip shape is not dependent on a cleavage plane of a crystal, versatility is also high.

[2] Preferably, the semiconductor substrate has a diameter not smaller than 150 mm.

In a large-area substrate having a diameter not smaller than 150 mm (for example, not smaller than 6 inches), a machining stress tends to unevenly be applied at the time of dicing. Therefore, when a substrate is higher in hardness, cracking is likely at a high frequency. According to the manufacturing method [1] above, however, even a large-area substrate as such can be divided without producing cracks.

[3] Preferably, the semiconductor layer has a thickness not smaller than 300 μm and not greater than 700 μum.

With a semiconductor layer having a thickness not smaller than 300 μm, warpage of a semiconductor substrate can be suppressed. Thus, defect of suctioning in a step of fixing a substrate onto a stage by suctioning process (for example, in an ion implantation step) can be prevented and generation of thermal strains can be lessened. In addition, with a semiconductor layer having a thickness not greater than 700 μm, undue cost can be suppressed.

A semiconductor layer having a thickness not smaller than 300 μm and not greater than 700 μm, however, is highly likely to crack as it is higher in hardness. When such a semiconductor layer is divided simply with the use of a dicing saw, cracks will be produced at a high frequency. Though details of a mechanism of such a phenomenon have not been known, such a phenomenon is estimated to have resulted from combined actions by residual strains in the substrate or a machining stress at the time of dicing.

According to the manufacturing method [1] above, even a semiconductor substrate including a semiconductor layer having a thickness which is likely to lead to cracking can be divided without producing cracks.

[4] Preferably, the first division step includes a step of obtaining four first individual pieces by dividing the semiconductor substrate along a cross, because a frequency of cracking can further be lowered.

[5] Preferably, the semiconductor layer has a Knoop hardness not lower than 1000 kgf/mm².

With the conventional division method, when a semiconductor layer has a Knoop hardness not lower than 1000 kgf/mm², it has been very difficult to divide the semiconductor substrate without producing cracks. According to the manufacturing method [1] above, however, division can readily be achieved.

[6] Preferably, the semiconductor layer includes at least any one of a silicon carbide layer, a sapphire layer, a gallium nitride layer, and a diamond layer.

According to the manufacturing method [1] above a semiconductor substrate including such a layer and having a high hardness can also be divided.

[7] Preferably, the first division step and the second division step are successively performed on the same stage, because a process can be simplified.

[8] Preferably, the semiconductor substrate further includes an insulating film formed on the epitaxial layer.

When an insulating film (for example, a passivation film or an interlayer insulating film) is formed on an epitaxial layer on a semiconductor substrate, residual strains increase due to a tensile stress and cracking is more likely at the time of division. In this case as well, according to the manufacturing method [1] above, a semiconductor substrate can be divided without producing cracks.

### Details of Embodiment of the Present Invention

An embodiment of the present invention (hereinafter also denoted as the “present embodiment”) will be described hereinafter in detail, however, the present embodiment is not limited thereto. In the description below, the same or corresponding elements have the same reference characters allotted and the same description thereof will not be repeated. In crystallographic denotation herein, an individual orientation, a group orientation, an individual plane, and a group plane are shown in [ ], < >, ( ), and { }, respectively. Moreover, a crystallographically negative index is normally expressed by a number with a bar “−” thereabove, however, it is herein expressed by a number preceded by a negative sign.

### Method of Manufacturing Semiconductor Device

FIG. 5 is a flowchart showing an overview of a manufacturing method in the present embodiment. Referring to FIG. 5, the manufacturing method includes preparing step (S100) and a dicing step (S200). The dicing step includes a first division step (S201) and a second division step (S202) in this order. Each step will be described below.

### Preparing Step (S100)

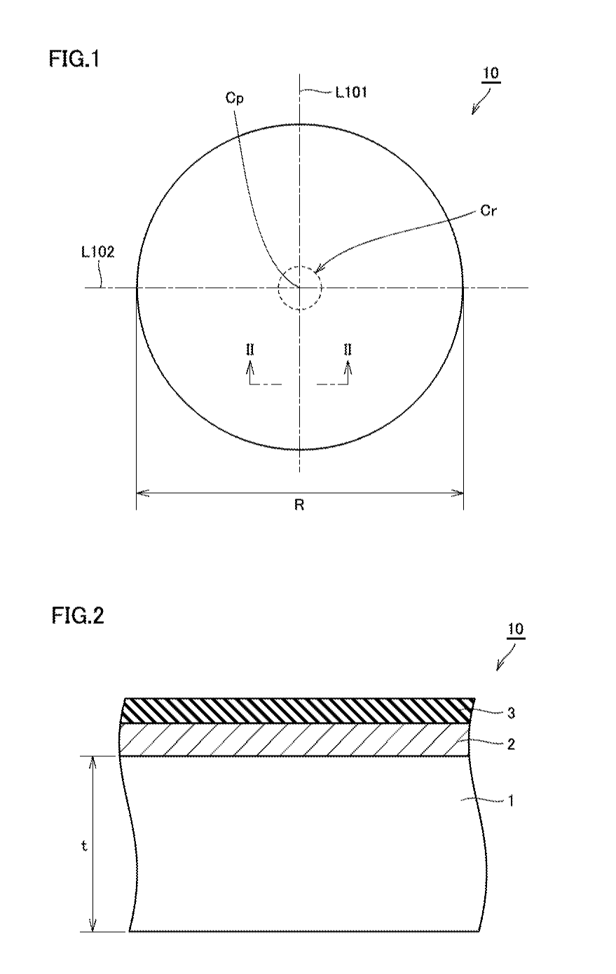

In this step, a semiconductor substrate 10 is prepared. FIG. 1 is a schematic plan view of semiconductor substrate 10 and FIG. 2 is a schematic partial cross-sectional view along the line II-II in FIG. 1.

### Semiconductor Substrate

Referring to FIGS. 1 and 2, semiconductor substrate 10 includes a semiconductor layer 1 and an epitaxial layer 2 formed on semiconductor layer 1, and semiconductor substrate 10 further includes an insulating film 3 on epitaxial layer 2. Semiconductor substrate 10 has a diameter R preferably not smaller than 150 mm (for example, not smaller than 6 inches), more preferably not smaller than 175 mm (for example, not smaller than 7 inches), and particularly preferably not smaller than 200 mm (for example, not smaller than 8 inches), because semiconductor substrate 10 greater in area can contribute to cost reduction of a semiconductor device.

### Semiconductor-Layer

Semiconductor layer 1 can include at least one of an SiC layer, a sapphire layer, a GaN layer, and a diamond layer. Semiconductor layer 1 may be formed from a single layer or may be constituted of a plurality of layers. For example, semiconductor layer 1 may be formed from a single SiC layer, or may be a stack in which a sapphire layer serves as an underlying layer and a GaN layer is stacked thereon.

The present embodiment is particularly effective for a semiconductor layer higher in hardness than an Si layer (a semiconductor layer having a Knoop hardness approximately not lower than 1000 kgf/mm²). As semiconductor layer 1 is higher in hardness, semiconductor substrate 10 is more likely to crack. Therefore, difference between yield according to the present embodiment and yield according to conventional dicing is significant. Here, Knoop harnesses of main semiconductor materials are listed as follows.

Si: from 560 to 710 kgf/mm²

Sapphire: from 1600 to 2000 kgf/mm²

SiC: from 2500 to 3200 kgf/mm²

Diamond: from 7000 to 8000 kgf/mm²

Therefore, semiconductor layer 1 has a hardness preferably not lower than 1000 kgf/mm², more preferably not lower than 1500 kgf/mm², further preferably not lower than 2000 kgf/mm², and most preferably not lower than 2500 kgf/mm².

Semiconductor layer 1 is prepared, for example, by slicing a single-crystal ingot. A single-crystal ingot is desirably sliced to a prescribed thickness, for example, with the use of a wire saw. After slicing, a main surface of semiconductor layer 1 may be polished. Semiconductor layer 1 has a thickness t preferably not smaller than 300 μm and not greater than 700 μm, because, when thickness t is not smaller than 300 μm, warpage of semiconductor substrate 10 is lessened, and for example, generation of thermal strains during ion implantation can be suppressed. By restricting thickness t to 700 μm or smaller, undue cost can also be suppressed. Semiconductor layer 1 has thickness t more preferably not smaller than 400 μm and not greater than 600 μm and particularly preferably not smaller than 450 μm and not greater than 550 μm.

When an aimed semiconductor device is a power device, semiconductor layer 1 is preferably formed from a layer of SiC having polytype of 4H (hereinafter also denoted as “4H-SiC”). When semiconductor layer 1 is formed from a 4H-SiC layer, a main surface (a growth surface) of main surfaces of semiconductor layer 1 where epitaxial layer 2 is to be formed may be on a (0001) plane [what is called an Si plane] side or may be on a (000-1) plane [what is called a C plane] side. Here, the growth surface is desirably a surface tilted by not smaller than 2° and not greater than 8° with respect to a {0001} plane. Namely, an off angle of semiconductor layer 1 with respect to the {0001} plane is desirably not smaller than 2° and not greater than 8° in order to suppress occurrence of basal plane dislocation in epitaxial layer 2 and to improve yield. In the description below, a main surface located opposite to the growth surface may be denoted as a “backside surface”.

### Epitaxial Layer

Epitaxial layer 2 is a semiconductor layer epitaxially grown on semiconductor layer 1. Epitaxial growth on semiconductor layer 1 can be carried out, for example, with chemical vapor deposition (CVD), molecular beam epitaxy (MBE), or liquid phase epitaxy (LPE). In an example of 4H-SiC, for example, with CVD in which a gas mixture of silane (SiH₄) and propane (C₃H₈) is used as a source gas, epitaxial layer 2 of 4H-SiC can be grown on a 4H-SiC layer (semiconductor layer 1). Here, epitaxial layer 2 may be doped, for example, with such an impurity as nitrogen (N) phosphorus (P).

Epitaxial layer 2 has an impurity region (not shown) doped with donors or acceptors. The impurity region is formed, for example, by implanting ions from above a mask patterned through lithography. Here, when epitaxial layer 2 is formed from an SiC layer, in order to suppress damages (defects) caused by ion implantation, a substrate should be heated approximately to 300° C. to 800° C. while the backside surface of semiconductor substrate 10 is fixed onto the stage. Thermal strains caused here may be one cause of tendency of cracking of an SiC substrate. As described previously, when semiconductor layer 1 has thickness t not smaller than 300 μm, warpage of semiconductor substrate 10 is lessened and thermal strains during ion implantation are suppressed. Thus, a frequency of occurrence of cracking at the time of dicing can be lowered.

Implanted donors or acceptors are activated by annealing semiconductor substrate 10 at a prescribed temperature. Thereafter, an electrode layer or the like may be formed, depending on a structure of an aimed device.

### Insulating Film

Referring to FIG. 2, semiconductor substrate 10 can further include insulating film 3 formed on epitaxial layer 2. Insulating film 3 is formed with CVD or sputtering, and functions, for example, as an interlayer insulating film and a passivation film (a protecting film). Insulating film 3 may be, for example, a silicon dioxide (SiO₂) film, a silicon nitride (SiN) film, a silicon oxynitride (SiON) film, or a resin film (for example, a polyimide film). Insulating film 3 may be formed from a single layer or may be constituted of a plurality of layers. Insulating film 3 has a thickness, for example, approximately from 0.5 μm to 2.0 μm.

As insulating film 3 is formed, a tensile stress is applied to semiconductor layer 1 and epitaxial layer 2, which promotes occurrence of cracking at the time of dicing. Therefore, for example, when an SiC substrate including an insulating film is divided (diced) with the conventional division method, cracks have been produced and yield has lowered. According to the division method in the present embodiment described below, even in such a case, a semiconductor substrate can be divided without producing cracks.

### Dicing Step (S200)

In the dicing step (S200), semiconductor substrate 10 is diced into chips. In the present embodiment, a general dicing saw can be employed. For a dicing blade, for example, a blade containing diamond abrasive grains in a cutting edge (what is called a diamond blade) can be employed. In the dicing step (S200), the first division step (S201) and the second division step (S202) are performed in this order.

### First Division Step (S200)

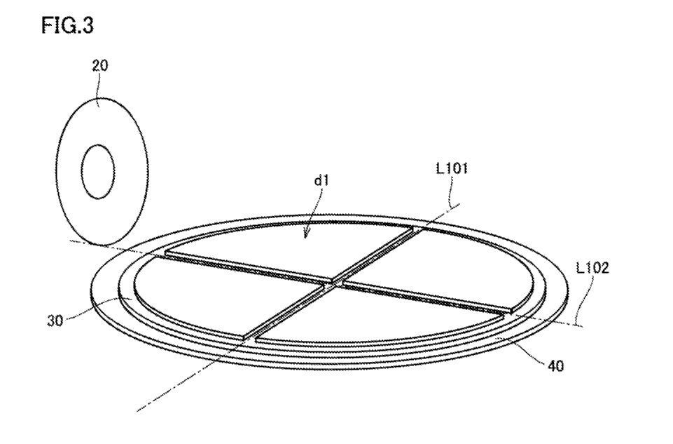

FIG. 3 is a schematic diagram illustrating the first division step. In this step, first individual pieces d1 are obtained by dividing semiconductor substrate 10. Referring to FIGS. 1 and 3, semiconductor substrate 10 is placed on a dicing stage 40 with a protecting tape 30 being stuck to the backside surface and a growth surface facing up. Then, first individual pieces d1 are obtained by cutting semiconductor substrate 10 with a dicing blade 20 along dicing lines L101 and L102 passing through a central region Cr including a central point Cp of semiconductor substrate 10 and having a diameter of 10 mm.

By thus carrying out initial division such that a machining stress applied to portions to be first individual pieces d1 is even, first individual pieces d1 can be obtained without producing cracks, with residual strains accumulated in semiconductor substrate 10 being released.

Though a case that there are two dicing lines is illustrated in FIGS. 1 and 3, one dicing line or three or more dicing lines may be provided in the first division step so long as the dicing line(s) pass(es) through central region Cr.

Central region Cr has a diameter more preferably of 8 mm and particularly preferably of 5 mm, because, as a diameter of central region Cr is restricted to be smaller, a frequency of occurrence of cracking can be lowered and the number of obtained chips can be increased.

Referring to FIGS. 1 and 3, in the first division step, preferably, semiconductor substrate 10 is divided along a cross to thereby obtain four first individual pieces d1, because a frequency of occurrence of cracking can further be lowered. Though dicing line L101 and dicing line L102 are desirably orthogonal to each other, two dicing lines do not necessarily have to be orthogonal so long as semiconductor substrate 10 can be divided along a cross. An angle of intersection between dicing line L101 and dicing line L102 is preferably not smaller than 85° and not greater than 95°, more preferably not smaller than 87° and not greater than 93°, and particularly preferably not smaller than 89° and not greater than 91°.

### Second Division Step (S202)

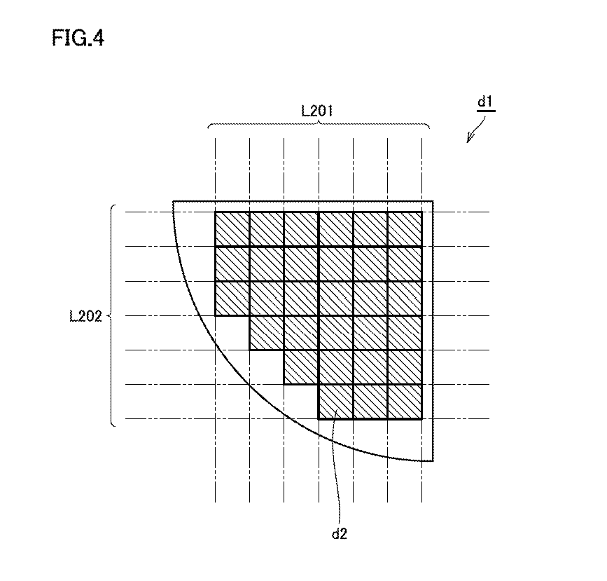

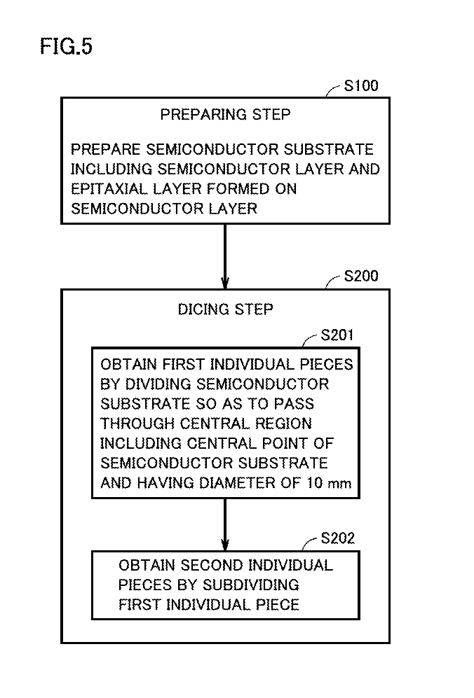

The second division step is performed after the first division step. FIG. 4 is a schematic diagram illustrating the second division step. In this step, a plurality of second individual pieces d2 (chips) are obtained by cutting first individual piece d1 along dicing lines L201 and L202. Since residual strains have already been eliminated from first individual piece dl which has gone through the first division step, dicing can be carried out without producing cracks, without special setting in the second division step.

The second division step is desirably performed consecutively in succession to the first division step on the same dicing stage 40 (see FIG. 3) for simplification of a process.

Through the steps above, even a semiconductor substrate high in hardness can be divided without producing cracks and yield of semiconductor devices can be improved.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a semiconductor device, comprising:
a step of preparing a semiconductor substrate including a semiconductor layer and an epitaxial layer formed on said semiconductor layer;
a first division step of obtaining first individual pieces by dividing said semiconductor substrate so as to pass through a central region including a central point of said semiconductor substrate and having a diameter of 10 mm; and
a second division step of obtaining second individual pieces by subdividing said first individual piece.

2. The method of manufacturing a semiconductor device according to claim 1, wherein
said semiconductor substrate has a diameter not smaller than 150 mm.

3. The method of manufacturing, a semiconductor device according to claim 1, wherein
said semiconductor layer has a thickness not smaller than 300 μm and not greater than 700 μm.

4. The method of manufacturing a semiconductor device according to claim 1, wherein
said first division step includes a step of obtaining four said first individual pieces by dividing said semiconductor substrate along a cross.

5. The method of manufacturing a semiconductor device according to claim 1, wherein
said semiconductor layer has a Knoop hardness not lower than 1000 kgf/mm².

6. The method of manufacturing a semiconductor device according to claim 1, wherein
said semiconductor layer includes at least any one of a silicon carbide layer, a sapphire layer, a gallium nitride layer, and a diamond laver.

7. The method of manufacturing a semiconductor device according to claim 1, wherein
said first division step and said second division step are successively performed on an identical stage.

8. The method of manufacturing a semiconductor device according to claim 1, wherein
said semiconductor substrate further includes an insulating film formed on said epitaxial layer.
